(19) United States
(12) Patent Application Publication
(10) Pub. No.: US 2006/0113547 A1
(43) Pub. Date: Jun. 1, 2006

(54) Methods of fabricating memory devices including fuses and load resistors in a peripheral circuit region

(75) Inventor: Kwang-Shik Shin, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/287,956

(22) Filed: Nov. 28, 2005

(30) Foreign Application Priority Data
Nov. 29, 2004 (KR) 10-2004-0098888

(51) Int. Cl. H01L 31/0312

(52) U.S. Cl. 257/77

(57) ABSTRACT

Methods of fabricating a semiconductor memory device include forming a plurality of memory cells in a cell region of a semiconductor substrate. An insulating layer is formed on the plurality of memory cells in the cell region and on a peripheral circuit region of the substrate, and a bit line contact plug is formed extending through the insulating layer to the substrate in the cell region. A continuous conductive layer is formed on the insulating layer in the cell region and the peripheral circuit region. The continuous conductive layer is patterned to define a bit line contact pad on the bit line contact plug in the cell region and at least one fuse in the peripheral circuit region, for example, using a same mask pattern. The continuous conductive layer may also be patterned to define a load resistor in the peripheral circuit region. Related devices are also discussed.

### CROSS-REFERENCE TO RELATED APPLICATION

This application claims priority under 35 U.S.C. §119 from Korean Patent Application No. 10-2004-0098888, filed Nov. 29, 2004, the disclosure of which is hereby incorporated by reference herein in its entirety.

### FIELD OF THE INVENTION

The present invention relates to semiconductor devices, and more particularly, to methods of fabricating memory devices.

### BACKGROUND OF THE INVENTION

Flash memory devices are nonvolatile memory devices, and as such, may retain stored data even when they are powered off. Flash memory devices may be classified as NOR flash memory devices or NAND flash memory devices depending on the structure of a cell array. NAND flash memory devices may be relatively low cost and/or may provide relatively low power consumption compared to NOR flash memory devices.

NAND flash memory devices may include memory cell transistors that store data, and a driving circuit that drives the memory cell transistors. The driving circuit may include a signal delay circuit, a high-voltage stabilizing circuit, a reference voltage generating circuit, and the like. The circuits may include a load resistor. The memory cell transistors may be formed in a cell area of a semiconductor substrate, while the driving circuit may be formed in a peripheral circuit area of the semiconductor substrate.

Millions of memory cell transistors may be formed in the cell area of the semiconductor substrate. If one or more of the memory cell transistors are defective, the NAND flash memory device may malfunction. Accordingly, redundant memory cells and fuses may be provided to replace the defective memory cell transistor(s) in the semiconductor substrate. Defective memory cell transistor(s) may be discovered in a test process, and the redundant memory cells may be substituted in a repair process. The repair process may include using a laser beam to cut corresponding fuse(s). When a fuse connected to a defective memory cell transistor is cut, electrical signals may be applied to a redundant memory cell rather than to the defective cell transistor.

Fuses may be formed in the peripheral circuit area. For example, fuses may be formed in conjunction with a control gate electrode layer, a bit line layer, and a metal wiring layer.

In forming fuses in conjunction with the control gate electrode, a floating gate layer and a dielectric layer may be sequentially stacked on a semiconductor substrate. The floating gate layer and the dielectric layer may be partially etched to expose a fuse region on the peripheral circuit area. The control gate electrode layer may be formed on the surface of the semiconductor substrate. The control gate electrode layer, the dielectric layer and the floating gate layer may be patterned to form a control gate electrode, a control gate dielectric layer and a floating gate in the cell area. At the same time, the control gate electrode layer may be patterned to form fuses in the fuse region. When the floating gate layer and the dielectric layer are removed from the fuse region, a step corresponding to the thickness of the floating gate layer and the dielectric layer may be formed between the cell area and the fuse region. Accordingly, when the control gate electrode layer is patterned, a “bridge” may be formed that may connect adjacent fuses, which may obstruct the repair process.

In forming fuses in conjunction with a bit line layer, a fuse may be formed in the peripheral circuit area, while a bit line is formed in the cell area. The fuse may be formed of the same material as the bit line. The bit line may be formed of a metal layer, such as a tungsten layer, with a relatively low resistivity and high melting points which may improve the transfer speed of electrical signals and the reliability of the device. However, where the fuse is formed in tungsten, a laser beam for cutting the fuse may require more power than that of a laser beam for cutting a polysilicon fuse or a tungsten silicide fuse. As the integration of the NAND flash memory device increases, the fuses may be increasingly reduced in pitch. As such, when a desired fuse is selected to be cut, non-selected fuses adjacent to the desired fuse may also be damaged or cut. After the repair process, the damaged or cut tungsten fuses may be exposed to air. The damaged or cut tungsten fuses may easily be oxidized and corroded due to moisture in the air, which may cause malfunctioning of the NAND flash memory device. In particular, since the tungsten layer may be oxidized at a higher rate than a polysilicon layer or a tungsten silicide layer, the damaged tungsten fuses may significantly degrade post-repair yield.

In forming fuses in conjunction with a metal wiring layer, fuses may be formed in a peripheral circuit area while metal wirings are formed. The metal wiring layer may be formed of a barrier metal layer and a metal layer that are stacked sequentially. For example, copper or aluminum may be used to form the metal layer. In addition, titanium or titanium nitride may be used to form the barrier metal layer. The metal layer may be formed to a thickness greater than that of the barrier metal layer. Accordingly, a relatively high-power laser beam may be required to cut through the metal wiring layer. Moreover, formation of the fuse with the metal wiring layer may require that the metal wiring layer have a relatively small thickness. For example, the fuse may be formed of only the barrier metal layer (i.e., by etching away and/or otherwise removing the metal layer), which may require a more complicated fabrication process.

### SUMMARY OF THE INVENTION

According to some embodiments of the present invention, a method of fabricating a semiconductor memory device may include forming a plurality of memory cells in a cell region of a semiconductor substrate. An insulating layer may be formed on the plurality of memory cells in the cell region and on a peripheral circuit region of the substrate, and a bit line contact plug may be formed extending through the insulating layer to the substrate in the cell region. A continuous conductive layer may be formed on the insulating layer in the cell region and the peripheral circuit region. The continuous conductive layer may be patterned to define a bit line contact pad on the bit line contact plug in the cell region and at least one fuse in the peripheral circuit region. The continuous conductive layer may also be patterned to define a load resistor in the peripheral circuit region.

In some embodiments, the continuous conductive layer may be patterned by etching the continuous conductive layer to define the bit line contact pad in the cell region and the at least one fuse in the peripheral circuit region using a same mask pattern. In other embodiments, the continuous conductive layer may be photolithographically patterned to define the bit line contact pad in the cell region and the at least one fuse in the peripheral circuit region using a same mask pattern.

In other embodiments, a second insulating layer may be formed on the bit line contact pad in the cell region and on the at least one fuse in the peripheral circuit region. A portion of the second insulating layer on the at least one fuse may be selectively removed to reduce a thickness of the second insulating layer on the at least one fuse. In addition, a second bit line contact plug may be formed extending through the second insulating layer in the cell region to electrically contact the bit line contact pad, and a bit line may be formed on the second insulating layer in the cell region to electrically contact the second bit line contact plug.

In some embodiments, a bit line contact opening may be formed extending through the insulating layer to the substrate. The continuous conductive layer may be formed on the insulating layer in the cell region to fill the bit line contact opening and thereby form the bit line contact plug.

In other embodiments, the at least one fuse may be at least one fusible interconnection configured to provide an electrical connection to a redundant memory cell.

In some embodiments, first and second select transistors may be formed in the cell region. The plurality of memory cells may be electrically connected in series between the first and second select transistors. The bit line contact plug may extend through the insulating layer to electrically contact a source/drain region of the first select transistor opposite the plurality of memory cells.

In other embodiments, a source contact plug may be formed extending through the insulating layer in the cell region to electrically contact a source/drain region of the second select transistor opposite the plurality of memory cells. The continuous conductive layer may be patterned to concurrently define the bit line contact pad and a source contact pad on the source contact plug in the cell region, and the at least one fuse and a load resistor in the peripheral circuit region.

In some embodiments, a source contact trench may be formed in the cell region. The source contact trench may extend through the insulating layer to the source/drain region of the second select transistor, and may extend along the substrate in a direction substantially perpendicular to active regions therein. The source contact trench may be filled with a conductive material to define a source contact line.

In other embodiments, a bit line contact opening may be formed in the cell region extending through the insulating layer to the source/drain region of the first select transistor, and a source contact opening may be formed in the cell region extending through the insulating layer to the source/drain region of the second select transistor. The bit line contact opening and the source contact opening may be filled with a conductive material to respectively define the bit line contact plug and the source contact plug. In some embodiments, the conductive material may be the continuous conductive layer.

In further embodiments, a conformal etch stop layer may be formed on the plurality of memory cells prior to forming the insulating layer. The insulating layer may have a higher etch rate than the etch stop layer.

In some embodiments, the continuous conductive layer may be a doped polysilicon layer, a tungsten layer, a tungsten silicide layer, and/or a cobalt silicide layer.

In other embodiments, each of the plurality of memory cells may respectively include a tunnel oxide layer on the substrate, a floating gate on the tunnel oxide layer, a gate oxide layer on the floating gate, and a control gate on the gate oxide layer. As such, the plurality of memory cells may be a plurality of flash memory cells.

According to other embodiments of the present invention, a method of fabricating a semiconductor memory device may include forming a plurality of memory cells in a cell region of a semiconductor substrate. An insulating layer may be formed on the plurality of memory cells in the cell region and on a peripheral circuit region of the substrate, and a bit line contact plug may be formed extending through the insulating layer to the substrate in the cell region. A continuous conductive layer may be formed on the insulating layer in the cell region and the peripheral circuit region, and the continuous conductive layer may be patterned to define a bit line contact pad on the bit line contact plug in the cell region and at least one load resistor in the peripheral circuit region.

In some embodiments, the continuous conductive may be formed of doped polysilicon. A doping concentration of the at least one load resistor may be adjusted to provide a desired resistance.

In other embodiments, the continuous conductive layer may be patterned to define the at least one load resistor having a predetermined length and/or width to provide a desired resistance.

According to further embodiments of the present invention, a semiconductor memory device may include a semiconductor substrate and a plurality of memory cells on the cell region of the substrate. The substrate may include a cell region and a peripheral circuit region. The device may further include an insulating layer on the plurality of memory cells in the cell region and on the peripheral circuit region, and a bit line contact plug extending through the insulating layer to the substrate in the cell region. In addition, the device may include a bit line contact pad on the bit line contact plug in the cell region, at least one fusible interconnection on the insulating layer in the peripheral circuit region, and a load resistor on the insulating layer in the peripheral circuit region. The bit line contact pad, the at least one fusible interconnection, and the load resistor may be formed from a continuous conductive layer using a same mask pattern. As such, the bit line contact pad, the at least one fusible interconnection, and the load resistor may be formed of a same material and/or may have a same thickness.

In accordance with some further embodiments of the present invention, a method for forming a NAND flash memory device may include preparing a semiconductor substrate having a cell area and a peripheral circuit area. Cell transistors serving to store data, a first select transistor serving to select a string, and a second select transistor serving to select a ground may be formed in the cell area. A first interlayer insulating film may be formed on the surface of the semiconductor substrate having the cell transistors, the first select transistor and the second select transistor. A drain contact hole that passes through the first interlayer insulating film and exposes a drain region of the first select transistor may be formed. A drain plug may be formed to fill the drain contact hole. A drain pad in contact with the drain plug may be formed on the first interlayer insulating film, and concurrently, fuses and a load resistor may be formed in the peripheral circuit area.

In some embodiments of the present invention, an etching stopper layer may be further formed between the transistors and the first interlayer insulating film. That is, a conformal etching stopper layer may be formed on the entire surface of the semiconductor substrate having the cell transistors, the first select transistor and the second select transistor. The etching stopper layer may be formed of a material layer having an etching selection ratio with the first interlayer insulating film. For example, the first interlayer insulating film may be formed of a high-density plasma oxide layer, and the etching stopper layer may be formed of a silicon nitride layer by chemical vapor deposition.

In other embodiments, a source contact hole may be concurrently formed to expose a source region of the second select transistor when the drain contact hole is formed. Alternatively, a source contact slit may be formed. Subsequently, a first resistive material layer that fills the drain contact hole may be formed on the surface of the semiconductor substrate. The first resistive material layer may be formed of doped polysilicon, tungsten, tungsten silicide and/or cobalt silicide. For example, the first resistive material layer may be formed of the doped polysilicon layer. The upper surface of the first interlayer insulating film may be then exposed by partially removing the first resistive material layer to form the drain plug. In this case, a source plug may be formed to fill the source contact hole. When the source contact slit is formed, a source line may be formed to fill the source contact slit. A second resistive material layer may be formed on the surface of the semiconductor substrate having the drain plug. The second resistive material layer may be formed of doped polysilicon, tungsten, tungsten silicide and/or cobalt silicide. For example, the second resistive material layer may be formed of the doped polysilicon layer. The drain pad in electrical contact with the drain plug and a source line in electrical contact with the source plug may be formed in the cell area by patterning the second resistive material layer. The fuses and the load resistor may be formed of the same material layer as that of the drain pad.

In yet other embodiments, a second interlayer insulating film may be formed on the surface of the semiconductor substrate having the drain pad, the fuses and the load resistor. A bit line plug may be formed which passes through the second interlayer insulating film and comes in electrical contact with the drain pad. A bit line may be formed in electrical contact with the bit line plug on the second interlayer insulating film.

In accordance with other embodiments of the present invention, a method of forming a NAND flash memory device may include forming a semiconductor substrate having a cell area and a peripheral circuit area. Cell transistors serving to store data, a first select transistor serving to select a string, and a second select transistor serving to select a ground may be formed in the cell area. A first interlayer insulating film may be formed on the surface of the semiconductor substrate having the cell transistors, the first select transistor and the second select transistor. A drain contact hole that passes through the first interlayer insulating film and exposes a drain region of the first select transistor may be formed. A first resistive material layer may be formed to fill the drain contact hole. A drain pad may be formed on the first interlayer insulating film by patterning the first resistive material layer, and concurrently, fuses and a load resistor may be formed in the peripheral circuit area. In some embodiments, the fuses and the load resistor may be formed of the same material layer as the drain pad.

### BRIEF DESCRIPTION OF THE DRAWINGS

FIG. 1 is a partial plan view of a NAND flash memory device including fuses and a load resistor according to some embodiments of the present invention;

FIGS. 2 to 5 are cross-sectional views taken along a line I-I′ of FIG. 1 illustrating methods of fabricating semiconductor memory devices according to some embodiments of the present invention;

FIG. 6 is a partial plan view of a NAND flash memory device including fuses and a load resistor according to further embodiments of the present invention; and

FIGS. 7 and 8 are cross-sectional views taken along a line II-II′ of FIG. 6 illustrating methods of fabricating semiconductor memory devices according to further embodiments of the present invention.

### DETAILED DESCRIPTION OF EMBODIMENTS OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

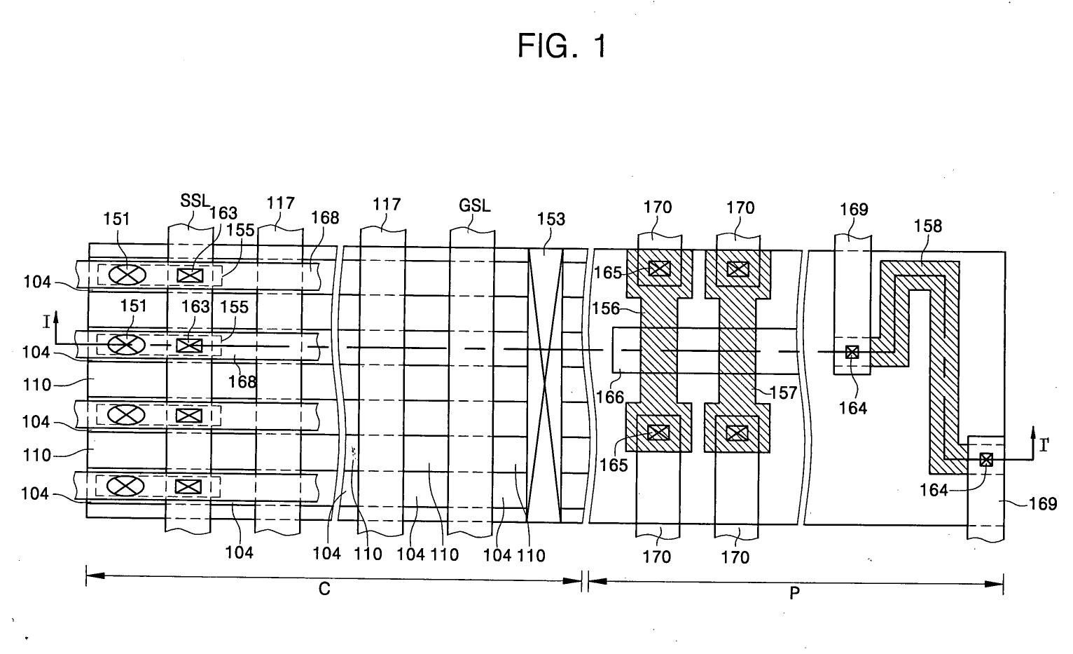

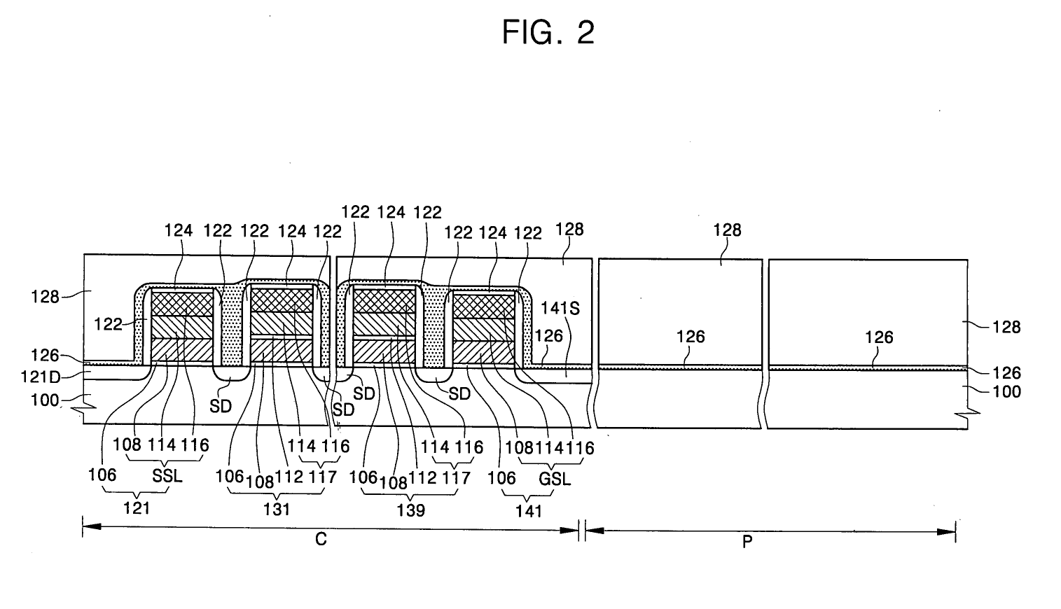

FIG. 1 is a partial plan view of a NAND flash memory device including fuses and a load resistor according to some embodiments of the present invention. FIGS. 2 to 5 are cross-sectional views taken along a line I-I′ of FIG. 1 to illustrate methods of fabricating a NAND flash memory device including fuses and a load resistor according to some embodiments of the present invention.

Referring now to FIGS. 1 and 2, a semiconductor substrate 100 is provided having a cell region/area C and a peripheral circuit region/area P. Memory cell transistors 131 and 139 (for storing data), a first select transistor 121 (i.e., a string select line SSL), and a second select transistor 141 (i.e., a ground select line GSL) are formed in the cell area C. The NAND flash memory device includes a plurality of strings that are formed in the cell area C. Each string includes the first select transistor 121, a plurality of memory cell transistors including memory cell transistors 131 and 139, and the second select transistor 141. For example, a string may include first memory cell transistor 131 to 32nd memory cell transistor 139 (i.e., 32 memory cell transistors) formed in an active region 104. The first cell transistor 131 has a drain connected to a source of the first select transistor 121. That is, a source/drain region SD is formed between the first select transistor 121 and the first cell transistor 131. Source/drain regions SD are also formed between the cell transistors 131 and 139. A source/drain region SD is also formed between the second select transistor 141 and the cell transistor 139. For example, the 32nd cell transistor 139 may have a source connected to a drain of the second select transistor 141. Further, additional transistors (not shown) which may be used in formation of a driving circuit, such as high-voltage transistors and/or low-voltage transistors, may be formed in the peripheral circuit area P.

As shown in FIGS. 1 and 2, device isolation layers 110 are formed in the semiconductor substrate 100 to define active regions 104. The semiconductor substrate 100 may be a first conductive type (e.g., P-type) silicon substrate. The device isolation layers 110 may be formed by a known technique, such as a shallow trench isolation (STI) process. As shown in FIG. 1, the active regions 104 formed in the cell area C may be substantially parallel when viewed from overhead. However, active regions (not shown) formed in the peripheral circuit area P may have different shapes that may be suitable for relevant circuits. A tunnel dielectric layer 106 is formed on the active regions 104. The tunnel dielectric layer 106 may be formed of a silicon oxide layer (SiO), a silicon oxynitride layer (SiON), and/or a high-k dielectric layer. The high-k dielectric layer may include an aluminum oxide layer (AlO), a hafnium oxide layer (HfO), a hafnium silicon oxide layer (HfsiO), a hafnium aluminum oxide layer (HfAlO), a tantalum oxide layer (TaO), a zirconium oxide layer (ZrO), and/or combinations thereof.

A first conductive layer is formed on the semiconductor substrate 100 and on the tunnel dielectric layer 106. The first conductive layer may be formed of a polysilicon layer. The first conductive layer is patterned to form a plurality of first conductive patterns 108 on the active regions 104. The first conductive patterns 108 are provided as floating gates 108 of the NAND flash memory device. As shown, the floating gates 108 are spaced apart at uniform intervals along the active regions 104 and have a substantially rectangular shape when viewed in a plan view. The floating gates 108 may also extend across the active region 104 and onto portions of the adjacent device isolation layer 110. Second conductive type (e.g., N-type) impurity ions may be implanted into the active region 104 using the floating gates 108 and the device isolation layer 110 as an ion implantation mask. As a result, the source/drain regions SD may be formed in the active regions 104 at both sides of the floating gates 108.

After the source/drain regions SD are formed, a conformal control gate dielectric layer 112 is formed on the surface of the semiconductor substrate 100. The control gate dielectric layer 112 may be formed conformally on upper surfaces and sidewalls of the floating gates 108 and on the active regions 104 and the device isolation layers 110 therebetween. When the floating gates 108 are formed to have substantially rectangular shape as described above, the control gate dielectric layer 112 may be formed on all four sidewalls of the floating gates 108. The control gate dielectric layer 112 may be formed of an oxide-nitride-oxide (ONO) layer and/or a high-k dielectric layer. A second conductive layer and a capping layer are then sequentially formed on the control gate dielectric layer 112. The second conductive layer may be formed by stacking a second lower conductive layer and a second upper conductive layer. For example, the second lower conductive layer may be formed of a polysilicon layer. The second upper conductive layer may be formed of a metal silicide layer, such as a tungsten silicide layer, a cobalt silicide layer and/or a nickel silicide layer, and/or a metal layer, such as tungsten. When the second lower conductive layer is a polysilicon layer and the second upper conductive layer is a tungsten layer, a tungsten nitride (WN) layer may be formed between the polysilicon layer and the tungsten layer. The capping layer may be formed of a silicon nitride layer (SiN).

A plurality of second parallel conductive patterns 117 and capping patterns 124 may be formed on the floating gates 108 and crossing over the active regions 104 and the device isolation layers 110 by sequentially patterning the capping layer, the second upper conductive layer and the second lower conductive layer. The second conductive patterns 117 include second lower conductive patterns 114 and second upper conductive patterns 116 sequentially stacked. The second conductive patterns 117 are provided as control gate electrodes 117 of the NAND flash memory device. The second conductive patterns 117 also act as word lines 117 of the NAND flash memory device. The second conductive layer and the capping layer may be patterned by a photolithographic and dry etching process. In such a process, the portions of the control gate dielectric layer 112 exposed between the word lines 117 may be etched and removed. The control gate dielectric layer 112 exposed between the word lines 117 may also act as an etch stop layer. As a result, the tunnel dielectric layers 106, the floating gates 108, the control gate dielectric layers 112 and the control gate electrodes 117 form the cell transistors 131 and 139 of the NAND flash memory device. The cell transistors 131 and 139 include source/drain regions SD formed at both sides of the floating gates 108.

The first select transistor 121 and the second select transistor 141 may be formed during the same fabrication steps as the cell transistors 131 and 139. The first select transistor 121 may be formed of the tunnel dielectric layer 106, the first conductive pattern 108, the second lower conductive pattern 114 and the second upper conductive pattern 116. In other words, the first select transistor 121 may not include the control gate dielectric layers 112 of the cell transistors 131 and 139. The capping pattern 124 may be formed on the first select transistor 121. The first select transistor 121 may serve to select the string of transistors connected thereto.

More particularly, the first conductive pattern 108, the second lower conductive pattern 114 and the second upper conductive pattern 116 form a string select line (SSL). A drain region 121D is formed at one side of the first select transistor 121 and a source region is formed at the opposite side. The source of the first select transistor 121 is connected to the drain of the first cell transistor 131. In other words, the source/drain region SD is formed between the first select transistor 121 and the first cell transistor 131.

The second select transistor 141 may be also formed of the tunnel dielectric layer 106, the first conductive pattern 108, the second lower conductive pattern 114 and the second upper conductive pattern 116. The capping pattern 124 may be formed on the second select transistor 141. The second select transistor 141 may serve to select a ground voltage. More particularly, the first conductive pattern 108, the second lower conductive pattern 114 and the second upper conductive pattern 116 form a ground select line (GSL). A source region 141S is formed at one side of the second select transistor 141, and a drain region is formed at the opposite side. The drain of the second select transistor 141 is connected to the source of the 32nd cell transistor 139. In other words, a source/drain region SD is formed between the second select transistor 141 and the 32nd cell transistor 139. Insulating spacers 122 are formed on sidewalls of the cell transistors 131 and 139, the capping patterns 124, the first select transistor 121 and the second select transistor 141. The insulating spacers 122 may be formed by forming a conformal silicon nitride layer on the surface of the semiconductor substrate 100, and anisotropically etching the silicon nitride layer. The insulating spacers 122 may be formed of a silicon oxide layer and a silicon nitride layer that are stacked sequentially.

As a result, the string select line (SSL), the ground select line (GSL), and a plurality of parallel word lines 117 therebetween are formed in the cell area C.

A conformal etch stop layer 126 is formed on the surface of the semiconductor substrate 100 including the cell transistors 131 and 139, the capping patterns 124, the insulating spacers 122, the first select transistor 121 and the second select transistor 141. A first insulating layer 128 is formed on the surface of the semiconductor substrate 100 including the etch stop layer 126. The first insulating layer 128 may be a silicon oxide layer formed by high-density plasma chemical vapor deposition (HDPCVD) (hereinafter referred to as a “high-density plasma oxide layer”). The etch stop layer 126 may be a material layer having with a higher etch rate than the first insulating layer 128. For example, when the first insulating layer 128 is a high-density plasma oxide layer, the etch stop layer 126 may be a silicon nitride layer formed by the chemical vapor deposition (CVD). Subsequently, an upper surface of the first insulating layer 128 may be planarized to reduce and/or minimize a step difference.

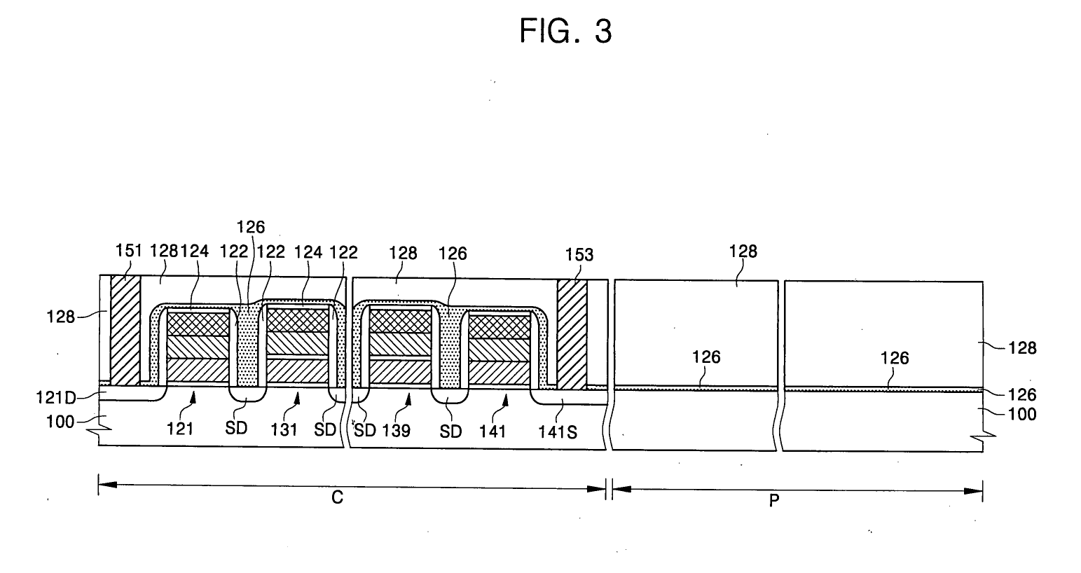

Referring to FIGS. 1 and 3, a drain contact hole is formed extending through the first insulating layer 128 and the etch stop layer 126 using a patterning process to expose the drain region 121D of the first select transistor 121. The patterning process may include forming a photo resist pattern on the first insulating layer 128 and sequentially etching the first insulating layer 128 and the etch stop layer 126 using the photo resist pattern as an etching mask. In the patterning process, the etch stop layer 126 may be used to selectively etch the insulating layer 128. In other words, as the etch stop layer 126 and the first insulating layer 128 are formed of different materials, the drain contact hole may be formed using an etchant having an etch selectivity between the etch stop layer 126 and the first insulating layer 128. For example, the drain contact hole may be formed to have a reverse-trapezoid shape having a lower width that is narrower than an upper width when viewed in cross-section, or a trapezoid shape having a lower width that is wider than an upper width. However, as shown in FIG. 3, the lower width may be substantially similar to the upper width.

A source contact trench or slit may be formed which exposes the source region 141S of the second select transistor 141 when the drain contact hole is formed. The source contact trench may be formed to extend parallel to the ground select line.

Subsequently, a first conductive material layer is formed on the surface of the substrate 100 to fill the drain contact hole and the source contact trench. The first conductive material layer may be formed of doped polysilicon, tungsten, tungsten silicide, and/or cobalt silicide. For example, the first conductive material layer may be formed of doped polysilicon. The first conductive material layer is partially removed to form a drain plug 151 within the drain contact hole. The drain plug 151 electrically connects the drain region 121D of the first select transistor 121 to a bit line, and as such, may also be referred to hereinafter as a bit line contact plug 151. A source line 153 may be formed within the source contact trench. The source line 153 is electrically connected to the source region 141S. To form the drain plug 151 and/or the source line 153, a chemical mechanical polishing (CMP) process (in which the first insulating layer 128 is used as a stop layer) may be used to partially remove the first conductive material layer.

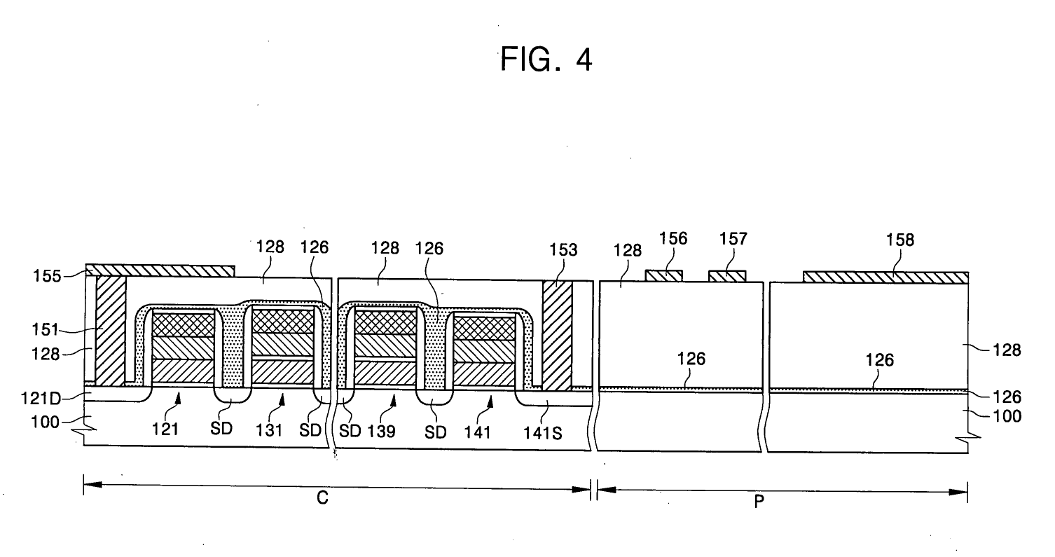

Referring to FIGS. 1 and 4, a continuous second conductive material layer is formed on the surface of the semiconductor substrate 100 to electrically contact the drain plug/bit line contact plug 151. The second conductive material layer may be formed of doped polysilicon, tungsten, tungsten silicide, and/or cobalt silicide. For example, the second conductive material layer may be formed of doped polysilicon. The second conductive material layer may be formed to a thickness of about 500 Å to about 3000 Å. The second conductive material layer is patterned to concurrently form a drain pad/bit line contact pad 155 in electrical contact with the drain plug 151 in the cell area C and fuses 156 and 157 and/or a load resistor 158 in the peripheral circuit area P, for example, using a same mask pattern. The fuses 156 and 157 may be fusible interconnections configured to be cut, for example, to replace one or more defective ones of the memory cell transistors 131 and 139 with redundant memory cell transistors. The fuses 156 and 157 may be formed to a suitable thickness to be cut by a laser beam in a repair process. The bit line contact pad/drain pad 155, the fuses 156 and 157, and/or the load resistor 158 may all be formed of the same material and may be formed to a similar thickness, which may simplify the fabrication process. However, electrical properties of the drain pad/bit line contact pad 155, the fuses 156 and 157, and/or the load resistor 158 may be subsequently adjusted. For example, when the load resistor 158 is formed of a doped polysilicon layer, doping concentrations of different portions of the doped polysilicon layer may be adjusted differently to obtain a desired resistance. In addition, a length and/or width of the load resistor 158 may be adjusted to obtain a desired resistance.

The drain pad/bit line contact pad 155 is electrically connected to the drain region 121D by the drain plug/bit line contact plug 151, which extends through the first insulating layer 128 and the etch stop layer 126.

In other embodiments of the present invention, the drain pad/bit line contact pad 155, the fuses 156 and 157, and/or the load resistor 158 may be formed of the first conductive material layer used to form the drain plug 151 and the source line 153. More particularly, as shown in FIG. 3, the first conductive material layer may be formed on the surface of the substrate 100 to fill the drain contact hole and the source contact trench. The first conductive material layer may be formed of doped polysilicon, tungsten, tungsten silicide and/or cobalt silicide. For example, the first conductive material layer may be formed of doped polysilicon. Subsequently, an upper surface of the first conductive material layer may be planarized to form a layer of the first conductive material on the first insulating layer 128 to a desired thickness. The planarized first conductive material layer is patterned to form the drain pad/bit line contact pad 155 in the cell area C, and concurrently, to form the fuses 156 and 157 and/or the load resistor 158 in the peripheral circuit area P. The source line 153 may also be concurrently formed within the source contact trench. Further, the drain pad/bit line contact pad 155 is electrically connected to the drain region 121D by the portion of the first conductive material layer that fills the drain contact hole.

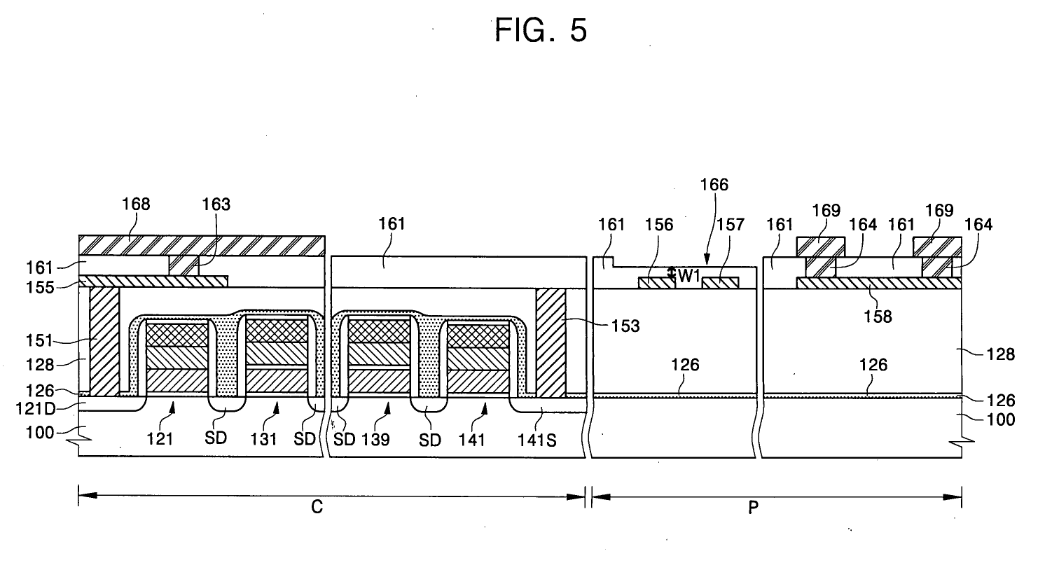

Referring to FIGS. 1 and 5, a second insulating layer 161 may be formed on the surface of the semiconductor substrate 100 including the drain pad 155, the fuses 156 and 157 and the load resistor 158. The second insulating layer 161 may be formed, for example, of a high-density plasma oxide layer. A bit line contact hole that exposes the drain pad 155 and metal wiring contact holes that expose the load resistor 158 may be formed by patterning the second insulating layer 161. A third conductive layer may be formed on the surface of the substrate 100 to fill the bit line contact hole and the metal wiring contact holes. A bit line plug 163 in electrical contact with the drain pad 155 and metal wiring plugs 164 in electrical contact with the load resistor 158 may be formed by planarizing the third conductive layer.

A bit line 168 in electrical contact with the bit line plug 163 and metal wirings 169 in electrical contact with the metal wiring plugs 164 may be formed on the second insulating layer 161. The bit line 168 and/or the metal wirings 169 may be formed concurrently with the bit line plug 163 and/or the metal wiring plugs 164, or may be formed in a subsequent fabrication step.

In addition, fuse plugs 165 and fuse wirings 170 connected to the fuses 156 and 157 may be formed, for example, when the bit line 168 and the metal wirings 169 are formed. The fuse plugs 165 and/or the fuse wirings 170 may also be formed prior to forming the bit line 168 and/or the metal wirings 169.

Thereafter, a third insulating layer (not shown) is additionally formed on the semiconductor substrate 100. The fuses 156 and 157 may be selected, for example, to be cut in a test process. The selected fuses may be combined to be cut by a laser beam. However, when the thick insulating layers (such as the second insulating layer 161 and the third insulating layer on the fuses 156 and 157 are relatively thick, cutting the fuses 156 and 157 may require a relatively high-powered laser beam. As such, it may be helpful to reduce the thickness of the insulating layers formed on the fuses 156 and 157. However, complete removal of the insulating layers formed on the fuses 156 and 157 may expose the fuses 156 and 157 to air. The exposed fuses 156 and 157 may be easily oxidized and/or corroded due to moisture in the air, which may cause malfunction of the NAND flash memory device. Accordingly, a groove 166 is formed in a region of the insulating layers above the fuses 156 and 157 by partially etching the second insulating layer 161 and the third insulating layer to remove portions thereof. As such, portions of the second insulating layer 161 remaining on the fuses 156 and 157 may have a thickness W1. The thickness W1 may be about 1000 Å to about 4000 Å. For example, the thickness W1 may be about 3000 Å.

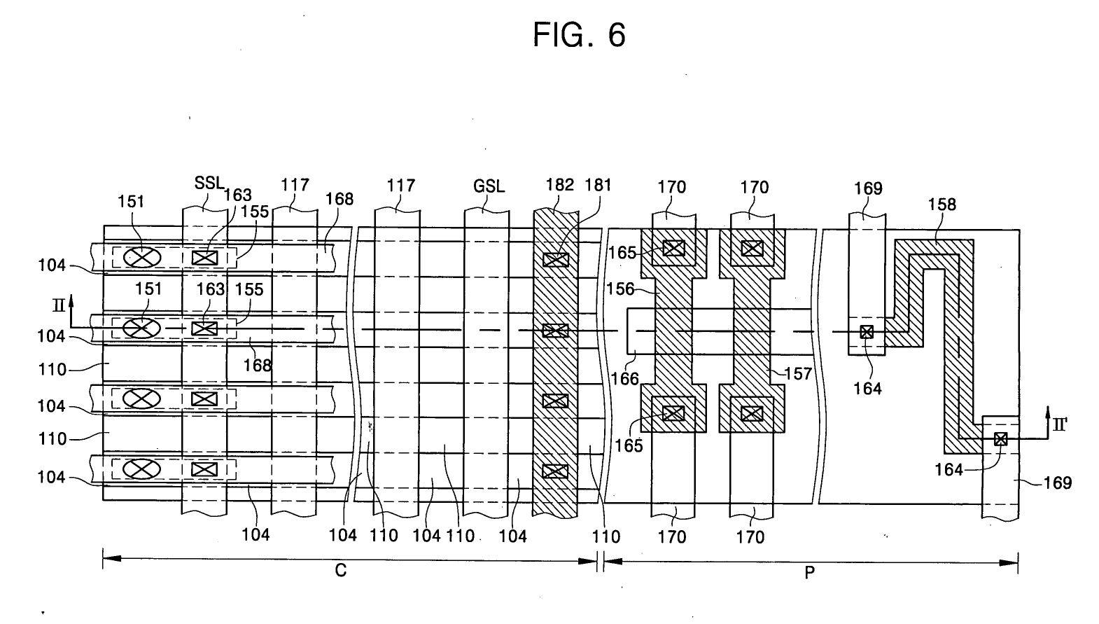

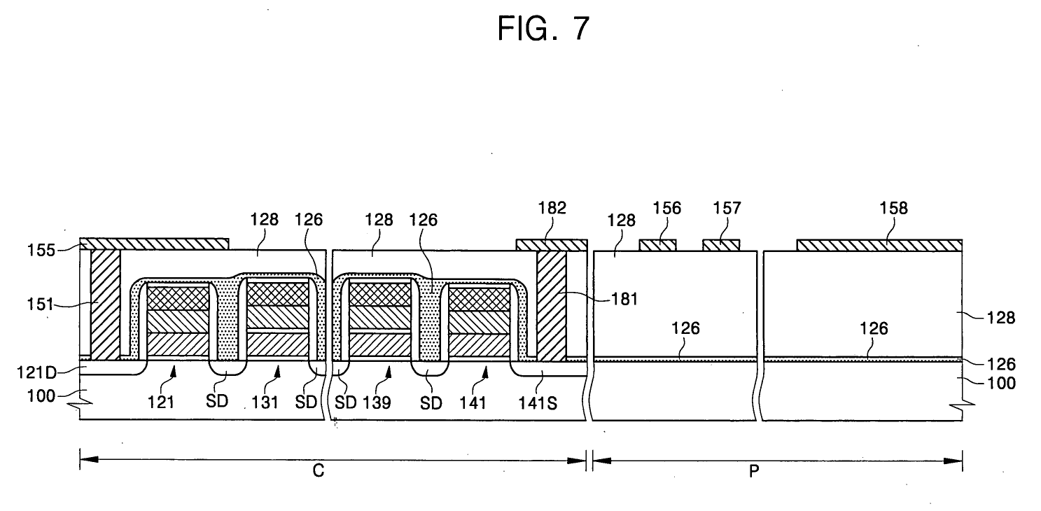

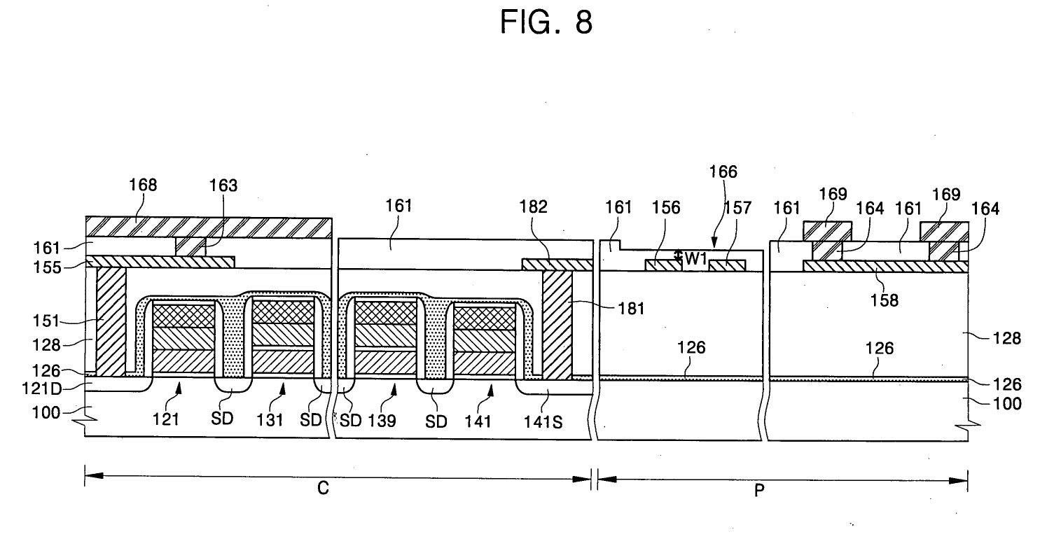

FIG. 6 is a partial plan view of a NAND flash memory device including fuses and a load resistor according to further embodiments of the present invention. FIGS. 7 and 8 are cross-sectional views taken along line II-II′ of FIG. 6 to illustrate methods of fabricating a NAND flash memory device including fuses and a load resistor according to further embodiments of the present invention. In FIGS. 6 to 8, source contact holes extending through the insulating layer 128 are provided to expose the source regions 141S of the second select transistor 141, rather than the source contact trench described with reference to FIGS. 1-5.

Referring now to FIGS. 6 and 7, a method of fabricating a NAND flash memory device including fuses and a load resistor according to further embodiments of the present invention includes providing a semiconductor substrate 100 having a cell region/area C and a peripheral circuit region/area P. Memory cell transistors 131 and 139 (for storing data), a first select transistor 121 (i.e., a string select line SSL), and a second select transistor 141 (i.e., a ground select line GSL) are formed in the cell area C. Accordingly, as described with reference to FIGS. 1 and 2, the string select line (SSL), the ground select line (GSL), and a plurality of parallel word lines 117 therebetween are formed in the cell area C. A conformal etch stop layer 126 is formed on the surface of the semiconductor substrate 100 including the cell transistors 131 and 139, capping patterns 124, insulating spacers 122, the first select transistor 121 and the second select transistor 141. A first insulating layer 128 is formed on the surface of the semiconductor substrate 100 including the etch stop layer 126.

A drain contact hole, which extends through the first insulating layer 128 and the etch stop layer 126 and exposes the drain region 121D of the first select transistor 121, is formed in the first insulating layer 128 and the etch stop layer 126 by a patterning process. The patterning process may include forming a photo resist pattern on the first insulating layer 128 and sequentially etching the first insulating layer 128 and the etch stop layer 126 using the photo resist pattern as an etching mask. In the patterning process, the etch stop layer 126 may be used to selectively etch the insulating layer 128. In other words, the drain contact hole may be formed by using an etchant having an etch selectivity between the etching stopper layer 126 and the first interlayer insulating film 128. A source contact hole may also be formed to expose the source region 141S of the second select transistor 141 when the drain contact hole is formed.

Subsequently, a first conductive material layer is formed on the surface of the substrate 100 to fill the drain contact hole and the source contact hole. The first conductive material layer may be formed of doped polysilicon, tungsten, tungsten silicide and/or cobalt silicide. For example, the first conductive material layer may be formed of doped polysilicon. The first conductive material layer is partially removed to form a drain plug/bit line contact plug 151 within the drain contact hole. A source contact plug 181 may also be formed within the source contact hole. In partially removing the first conductive material layer to form the drain plug 151 and/or the source contact plug 181, a chemical mechanical polishing (CMP) process may be employed using the first insulating layer 128 as a stop layer.

A continuous second conductive material layer is formed on the surface of the semiconductor substrate 100 to electrically contact the drain plug 151 and the source contact plug 181. The second conductive material layer may be formed of doped polysilicon, tungsten, tungsten silicide and/or cobalt silicide. For example, the second conductive material layer may be formed of doped polysilicon. The second conductive material layer is patterned to concurrently form a drain pad/bit line contact pad 155 in contact with the drain plug 151 and a source line 182 in contact with the source contact plug 181 in the cell area C, and to concurrently form fuses 156 and 157 and a load resistor 158 in the peripheral circuit area P, for example, using a same mask pattern. The source line 182 may be formed to extend parallel to the ground select line GSL.

The drain pad/bit line contact pad 155, the source line 182, the fuses 156 and 157 and/or the load resistor 158 may be all formed of the same material, which may simplify the fabrication process. For example, when the load resistor 158 is formed of doped polysilicon, the doping concentrations of different portions of the doped polysilicon layer may be adjusted differently to obtain a desired resistance. In addition, the drain pad/bit line contact pad 155, the source line 182, the fuses 156 and 157, and the load resistor 158 may be formed to a same thickness. The length and/or width of the load resistor 158 may be adjusted to obtain the desired resistance. The drain pad 155 is electrically connected to the drain region 121D by the drain plug 151, which extends though the first insulating layer 128 and the etch stop layer 126. Further, the source line 182 is electrically connected to the source region 141S by the source contact plug 181, which extends through the first insulating layer 128 and the etch stop layer 126.

In other embodiments of the present invention, the drain pad/bit line contact pad 155, the source line 182, the fuses 156 and 157 and/or the load resistor 158 may be formed of the first conductive material layer. More specifically, the first conductive material layer may be formed on the surface of the substrate 100 to fill the drain contact hole and the source contact hole. The first conductive material layer may be formed of doped polysilicon, tungsten, tungsten silicide and/or cobalt silicide. For example, the first conductive material layer may be formed of doped polysilicon. The upper surface of the first conductive material layer may be planarized and patterned to concurrently form the drain pad/bit line contact pad 155 and the source line 182 in the cell area C, and the fuses 156 and 157 and the load resistor 158 in the peripheral circuit area P. The drain pad 155 is electrically connected to the drain region 121D by the portion of the first conductive material layer that fills the drain contact hole. Further, the source line 182 is electrically connected to the source region 141S by the portion of the first conductive material layer that fills the source contact hole.

Referring to FIGS. 6 and 8, a second insulating layer 161 is formed on the surface of the semiconductor substrate 100 including the drain pad/bit line contact pad 155, the source line 182, the fuses 156 and 157 and the load resistor 158. The second insulating layer 161 may be formed of a high-density plasma oxide layer. A bit line contact hole that exposes the drain pad 155 and metal wiring contact holes that expose the load resistor 158 may be formed by patterning the second insulating layer 161. A third conductive layer may be formed on the surface of the substrate 100 to fill the bit line contact hole and/or the metal wiring contact holes. A bit line plug 163 in electrical contact with the drain pad/bit line contact pad 155 and metal wiring plugs 164 in electrical contact with the load resistor 158 may be formed by patterning the third conductive layer.

A bit line 168 in electrical contact with the bit line plug 163 and metal wirings 169 in electrical contact with the metal wiring plugs 164 may be formed on the second insulating layer 161. The bit line 168 and/or the metal wirings 169 may be formed concurrently with the bit line plug 163 and/or the metal wiring plugs 164, or may be formed in a subsequent fabrication step.

In addition, fuse plugs 165 and fuse wirings 170 connected to the fuses 156 and 157 may be formed, for example, when the bit line 168 and the metal wirings 169 are formed. The fuse plugs 165 and/or the fuse wirings 170 may also be formed prior to forming the bit line 168 and/or the metal wirings 169 are formed.

Thereafter, a third insulating layer (not shown) may be formed on the semiconductor substrate 100. A groove 166 may be formed in a region of the insulating layers adjacent the fuses 156 and 157 by partially etching the second insulating layer 161 and the third insulating layer to remove portions thereof. As such, a portion of the second insulating layer 161 remaining on the fuses 156 and 157 may have a thickness W1. The thickness W1 may be about 1000 Å to about 4000 Å. For example, the thickness W1 may be about 3000 Å.

As described above, according to some embodiments of the present invention, a drain pad/bit line contact pad is formed in electrical contact with a drain plug on a first insulating layer in a cell area, and concurrently, fuses and/or a load resistor are formed in a peripheral circuit area. The drain pad/bit line contact pad, the fuses and/or the load resistor may be all formed of the same material. Further, the drain pad/bit line contact pad, the fuses, and/or the load resistor may be concurrently formed using a same fabrication step and/or mask pattern, which may simplify the fabrication process. In addition, a variety of materials may be used to form the fuses. As such, fuses that are more easily cut in a repair process may be provided.

In the drawings and specification, there have been disclosed embodiments of the invention and, although specific terms are employed, they are used in a generic and descriptive sense only and not for purposes of limitation, the scope of the invention being set forth in the following claims.

That which is claimed:

1. A method of fabricating a semiconductor memory device, the method comprising:
forming a plurality of memory cells in a cell region of a semiconductor substrate;
forming an insulating layer on the plurality of memory cells in the cell region and on a peripheral circuit region of the substrate;
forming a bit line contact plug extending through the insulating layer to the substrate in the cell region;
forming a continuous conductive layer on the insulating layer in the cell region and the peripheral circuit region; and
patterning the continuous conductive layer to define a bit line contact pad on the bit line contact plug in the cell region and at least one fuse in the peripheral circuit region.

2. The method of claim 1, wherein patterning the continuous conductive layer further comprises:
patterning the continuous conductive layer to define the bit line contact pad in the cell region and to define the at least one fuse and a load resistor in the peripheral circuit region.

3. The method of claim 1, wherein patterning the continuous conductive layer comprises:
etching the continuous conductive layer to define the bit line contact pad in the cell region and the at least one fuse in the peripheral circuit region using a same mask pattern.

4. The method of claim 1, wherein patterning the continuous conductive layer comprises:
photolithographically patterning the continuous conductive layer to define the bit line contact pad in the cell region and the at least one fuse in the peripheral circuit region using a same mask pattern.

5. The method of claim 1, further comprising:
forming a second insulating layer on the bit line contact pad in the cell region and on the at least one fuse in the peripheral circuit region; and
selectively removing a portion of the second insulating layer on the at least one fuse to reduce a thickness thereof.

6. The method of claim 5, further comprising:
forming a second bit line contact plug extending through the second insulating layer in the cell region to electrically contact the bit line contact pad; and
forming a bit line on the second insulating layer in the cell region and to electrically contact the second bit line contact plug.

7. The method of claim 1, wherein forming the bit line contact plug comprises:
forming a bit line contact opening extending through the insulating layer to the substrate, wherein forming the continuous conductive layer further comprises forming the continuous conductive layer on the insulating layer in the cell region to fill the bit line contact opening.

8. The method of claim 1, wherein the at least one fuse comprises at least one fusible interconnection configured to provide an electrical connection to a redundant memory cell.

9. The method of claim 1, further comprising:
forming first and second select transistors in the cell region,
wherein the plurality of memory cells are electrically connected in series between the first and second select transistors, and wherein the bit line contact plug extends through the insulating layer to electrically contact a source/drain region of the first select transistor opposite the plurality of memory cells.

10. The method of claim 9, further comprising:
forming a source contact plug extending through the insulating layer in the cell region to electrically contact a source/drain region of the second select transistor opposite the plurality of memory cells.

11. The method of claim 10, wherein patterning the continuous conductive layer further comprises:
patterning the continuous conductive layer to concurrently define the bit line contact pad and a source contact pad on the source contact plug in the cell region, and the at least one fuse and a load resistor in the peripheral circuit region.

12. The method of claim 10, wherein forming the source contact plug comprises:
forming a source contact trench in the cell region extending through the insulating layer to the source/drain region of the second select transistor and extending along the substrate in a direction substantially perpendicular to active regions therein; and
filling the source contact trench with a conductive material.

13. The method of claim 10, wherein forming the bit line contact plug and forming the source contact plug comprises:
forming a bit line contact opening in the cell region extending through the insulating layer to the source/drain region of the first select transistor;
forming a source contact opening in the cell region extending through the insulating layer to the source/drain region of the second select transistor; and
filling the bit line contact opening and the source contact opening with a conductive material to respectively define the bit line contact plug and the source contact plug.

14. The method of claim 13, wherein the conductive material comprises the continuous conductive layer.

15. The method of claim 1, further comprising:
forming a conformal etch stop layer on the plurality of memory cells prior to forming the insulating layer thereon,
wherein the insulating layer has a higher etch rate than the etch stop layer.

16. The method of claim 1, wherein the continuous conductive layer comprises a doped polysilicon layer, a tungsten layer, a tungsten silicide layer, and/or a cobalt silicide layer.

17. The method of claim 1, wherein each of the plurality of memory cells respectively comprises:
a tunnel oxide layer on the substrate;
a floating gate on the tunnel oxide layer;
a gate oxide layer on the floating gate; and
a control gate on the gate oxide layer.

18. A method of fabricating a semiconductor memory device, the method comprising:
forming a plurality of memory cells in a cell region of a semiconductor substrate;
forming an insulating layer on the plurality of memory cells in the cell region and on a peripheral circuit region of the substrate;
forming a bit line contact plug extending through the insulating layer to the substrate in the cell region;
forming a continuous conductive layer on the insulating layer in the cell region and the peripheral circuit region; and
patterning the continuous conductive layer to define a bit line contact pad on the bit line contact plug in the cell region and at least one load resistor in the peripheral circuit region.

19. The method of claim 18, wherein the continuous conductive layer comprises doped polysilicon, the method further comprising:
adjusting a doping concentration of the at least one load resistor to provide a desired resistance.

20. The method of claim 18, wherein patterning the continuous conductive layer comprises:
patterning the continuous conductive layer to define the at least one load resistor having a predetermined length and/or width to provide a desired resistance.

21. A semiconductor memory device, comprising:
a semiconductor substrate including a cell region and a peripheral circuit region;
plurality of memory cells on the cell region of the substrate;
an insulating layer on the plurality of memory cells in the cell region and on the peripheral circuit region;
a bit line contact plug extending through the insulating layer to the substrate in the cell region;
a bit line contact pad on the bit line contact plug in the cell region;
at least one fusible interconnection on the insulating layer in the peripheral circuit region; and
a load resistor on the insulating layer in the peripheral circuit region,
wherein the bit line contact pad, the at least one fusible interconnection, and the load resistor comprise a same material and have a same thickness and are formed from a continuous conductive layer using a same mask pattern.
